(19) United States
(12) Patent Application Publication
(10) Pub. No.: US 2023/0260812 A1
(43) Pub. Date: Aug. 17, 2023

(54) CASSETTE HOLD DOWN

(71) Applicant: ENTEGRIS, INC., Billerica, MA (US)

(72) Inventors: Sin Ghun Lim, Butterworth (MY); Gian Ping Chua, Kulim (MY); Mohamad Zakaria Abd Mutholib, Kulim (MY)

(21) Appl. No.: 18/020,830

(22) PCT Filed: Aug. 10, 2021
(86) PCT No.: PCT/US2021/045434

§ 371 Date: Feb. 10, 2023

Related U.S. Application Data
(60) Provisional application No. 63/064,259, filed on Aug. 11, 2020.

(51) Int. Cl. H01L 21/673

(52) U.S. Cl. CPC H01L 21/67369; H01L 21/67386

(57) ABSTRACT

A cassette hold down includes a frame, a first cassette contact extending in a vertical direction with respect to the frame, and a second cassette contact extending in the same vertical direction. The first and second cassette contacts are separated along a length direction of the frame. The cassette contacts can contact a wafer cassette on either side of a horizontal bar of the wafer cassette that interfaces with a channel provided on a door for a wafer container including the cassette and cassette hold down. The second cassette contact can be joined to the frame by a spring. Mounting features such as bosses can be included to connect the cassette hold down to the wafer container. Hard stops extending opposite the cassette contacts can be included to limit travel of the cassette contacts by mechanical interference with the wafer container.

### FIELD

This disclosure is directed to a cassette hold down for a wafer container, particularly one including multiple contact points for contacting a wafer cassette.

### BACKGROUND

Wafer containers can include a wafer cassette contained with an outer pod. The wafer cassette may move with respect to the rest of the pod when moved or exposed to shocks such as being dropped, bumped, or the like. The movement of the wafer cassette can lead to damage to the pod, cassette, or wafers, or lead to undesirable particle generation. The movement of the wafer cassette can also dislodge the wafer cassette from other retention features such as a door guide included in the door of the wafer container.

### SUMMARY

This disclosure is directed to a cassette hold down for a wafer container, particularly one including multiple contact points for contacting a wafer cassette.

By using multiple contact points spaced apart from a horizontal bar engaging with the wafer cassette and on opposing sides of the horizontal bar, a cassette hold down can secure the wafer cassette on either side of the horizontal bar such that rotational movement and displacement of the wafer cassette can be better controlled and the wafer cassette can be better retained within a door guide that accommodates the horizontal bar.

In an embodiment, a cassette hold down includes a frame, a first cassette contact extending from the frame in a vertical direction on a first side of the frame and a second cassette contact extending from the frame in the vertical direction on the first side the of the frame. The first cassette contact is spaced apart from the second cassette contact in a length direction of the frame.

In an embodiment, the cassette hold down further includes a plurality of mounting bosses, each of the mounting bosses extending in the vertical direction on a second side of the cassette hold down, opposite the first side.

In an embodiment, each of the first cassette contact and the second cassette contact each include one or more stoppers extending in the vertical direction on a second side of the cassette hold down, opposite the first side, and each of the one or more stoppers are positioned on one of the first cassette contact or the second cassette contact.

In an embodiment, the cassette hold down further includes a spring connecting the second cassette contact to the frame, the spring configured to allow vertical movement of the second cassette contact relative to the frame.

In an embodiment, a wafer container includes a pod including one or more side walls, a closed end, an internal space defined by the one or more side walls and the closed end, and an open end, and a door. The door is configured to close the open end of the pod, the door including a channel. The wafer container further includes a wafer cassette including a bar configured to be received in the channel of the door. The wafer container further includes a cassette hold down. The cassette hold down includes a frame, a first cassette contact extending from the frame in a vertical direction on a first side of the frame, and a second cassette contact extending from the frame in the vertical direction on the first side the of the frame. When the wafer cassette and the cassette hold down are located in the internal space and the door is closing the open end, the first cassette contact and the second cassette contact are in contact with the wafer cassette on opposing sides of the bar, in the plane of the door.

In an embodiment, a side of the closed end facing the internal space includes a plurality of mounting features, and the cassette hold down includes a plurality of mounting bosses each configured to engage with at least one of said mounting features. In an embodiment, each of the plurality of mounting features is a hole formed in the side of the closed end facing the internal space.

In an embodiment, the cassette hold down includes a plurality of stoppers configured to extend towards a side of the closed end facing the internal space when the wafer cassette and the cassette hold down are located in the internal space and the door is closing the open end, and each of the plurality of stoppers are positioned on one of the first cassette contact or the second cassette contact.

In an embodiment, the wafer container further includes a spring connecting the second cassette contact to the frame, the spring configured to allow vertical movement of the second cassette contact relative to the frame.

In an embodiment, the wafer container is a standard mechanical interface (SMIF) pod.

### DRAWINGS

FIG. 1 shows a perspective view of a cassette hold down according to an embodiment.

FIG. 2 shows an exploded view of a wafer container including a cassette hold down according to an embodiment.

FIG. 3 shows a top view of a wafer cassette, a wafer container door, and a cassette hold down according to an embodiment.

FIG. 4 shows a sectional view of a door of a wafer container, a wafer cassette, and a cassette hold down according to an embodiment.

FIG. 5A shows a bottom view of a pod of a wafer container according to an embodiment.

FIG. 5B shows a bottom view of the pod of a wafer container shown in FIG. 5A and a cassette hold down according to an embodiment.

FIG. 6 shows a top view of a door of a wafer container according to an embodiment.

### DETAILED DESCRIPTION

This disclosure is directed to a cassette hold down for a wafer container, particularly one including multiple contact points for contacting a wafer cassette.

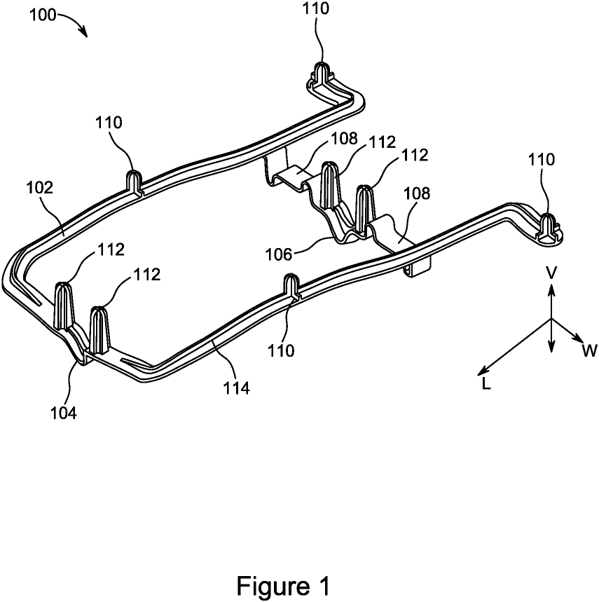

FIG. 1 shows a perspective view of a cassette hold down according to an embodiment. Cassette hold down 100 includes frame 102, first cassette contact 104, second cassette contact 106, one or more springs 108, mounting bosses 110, and stoppers 112. Ribs 114 can be provided along portions of the frame 102.

Cassette hold down 100 is a part configured to be included in a wafer container to restrict movement of a wafer cassette contained within. The cassette hold down can be mounted to part of the wafer container other than and apply pressure to the wafer cassette at contact points, such as those provided by first cassette contact 104 and second cassette contact 106. Cassette hold down 100 can include materials suitable for contact with or presence within a wafer container for semiconductor wafers. The cassette hold down 100 can include one or more polymeric materials. In an embodiment, cassette hold down 100 includes polycarbonate at one or more of first cassette contact 104, second cassette contact 106, springs 108, mounting bosses 110, or stoppers 112. In an embodiment, the entire cassette hold down 100 is polycarbonate.

Frame 102 forms the body of cassette hold down 100. Frame 102 can connect the other elements of cassette hold down 100, including first cassette contact 104 and mounting bosses 110, along with second cassette contact 106 or springs 108. Frame 102 can include one or more beams connecting these elements. Frame 102 has a length direction L and a width direction W, and a vertical direction V is perpendicular to the plane formed by the L and W. In an embodiment, the frame 102 is flexible and resilient such that the first cassette contact 104 can be deflected in the vertical direction when force is applied, for example by contact of the first cassette contact 104 with a wafer cassette.

First cassette contact 104 is a first point configured to contact a wafer cassette. First cassette contact 104 extends from the frame 102 in the vertical direction V such that it can contact the wafer cassette. The first cassette contact 104 can be at one end of the frame 102 in the length direction L. First cassette contact 104 can be positioned such that when cassette hold down 100 is installed into a wafer container, the first cassette contact 104 is not along a horizontal bar of the wafer cassette in the length direction L of the frame 102.

Second cassette contact 106 is a second point configured to contact the wafer cassette. Second cassette contact extends from frame 102 in the vertical direction V such that it can contact a wafer cassette that is also being contacted by the first cassette contact 104. Second cassette contact 106 can be spaced apart from first cassette contact 104 in the length direction L of frame 102. The spacing between first and second cassette contacts 104 and 106 can be such that one of first cassette contact 104 and second cassette contact 106 is on a first side of a horizontal bar included in the wafer cassette, and the other of first cassette contact 104 and second cassette contact 106 is on a second side of the horizontal bar, opposite the first.

One or more springs 108 can join second cassette contact 106 to the frame 102. Each spring 108 can be a resilient member configured to allow vertical travel of the second cassette contact when force is applied, for example force from the second cassette contact 106 being pressed against a wafer cassette. The spring 108 can be provided on one or both sides of second cassette contact 106 between the second cassette contact 106 and the frame 102. The spring 108 can include one or more bends. In an embodiment, each spring 108 is the same material as frame 102. In an embodiment, each spring 108 is polycarbonate.

Mounting bosses 110 can be one or more vertical projections from frame 102 extending in the vertical direction on a side of frame 102 opposite the direction first cassette contact 104 and 106 extend vertically from frame 102. The mounting bosses 110 can include one or more features configured to engage with one or more engagement features provided in a part of a wafer container such as a pod that the cassette hold down 100 is to be installed into. The mounting bosses 110 can be positioned in locations corresponding to the relative positions of the engagement features of the wafer container that the mounting bosses 110 will engage with. The mounting bosses 110 can be, for example, projections having a plus-sign-shaped cross section, that are sized to press-fit into holes provided in corresponding locations on an inner surface of the pod that cassette hold down 100 is to be installed into. The mounting bosses 110 can have any suitable shape or size for interfacing with the pod to stably retain the cassette hold down 100 within the pod when assembled.

Stoppers 112 are vertical projections from each of first cassette contact 104 and second cassette contact 106. The stoppers 112 extend vertically in an opposite direction from first and second cassette contacts 104 and 106. The stoppers 112 can be configured such that they extend a height less than the distance between first cassette contact 104 or second cassette contact 106 and the wafer container. The height of stoppers 112 can be selected such that they do not ordinarily contact the wafer container when the wafer container is assembled including the cassette hold down 100. The stoppers can be spaced apart from the wafer container by a gap sized such that the stoppers 112 can contact the wafer container during a mechanical shock event (i.e. sudden acceleration or deceleration such as being dropped, struck, or the like) to stop further movement of first cassette contact 104 and/or second cassette contact 106 beyond a certain amount.

Ribs 114 can extend vertically from some or all of the frame 102 and/or portions of the first and second cassette contacts 104 and 106. Ribs 114 can provide mechanical reinforcement of the portions where they are provided, for example to reduce deflection of those portions in the vertical direction when force is applied to the cassette hold down 100. In an embodiment, ribs 114 are provided both on upper and lower surfaces of the frame 102, forming a plus or cross shape in the cross-section of frame 102 where those ribs 114 is provided. The ribs 114 can reinforce frame 102 such that the retention force applied by the cassette hold down 100 is increased.

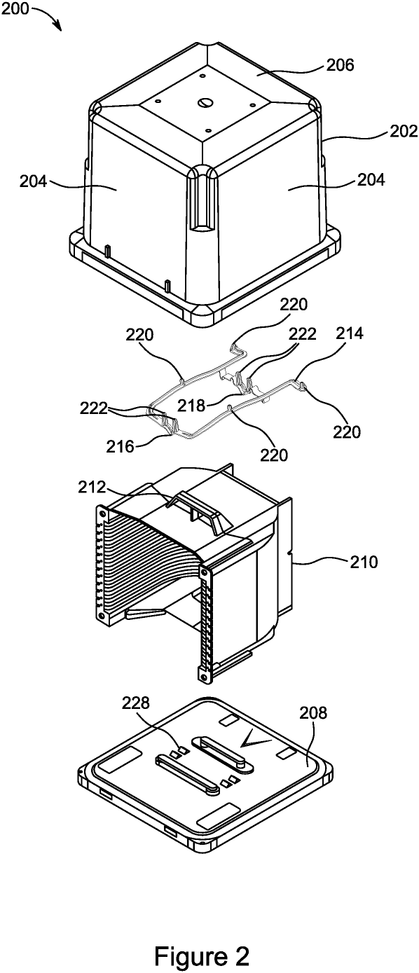

FIG. 2 shows an exploded view of a wafer container including a cassette hold down according to an embodiment. The wafer container 200 includes a pod 202 having one or more side walls 204 and closed end 206, a door 208, a wafer cassette 210 including a handle 212, and a cassette hold down 214.

Wafer container 200 is a wafer container including wafer cassette 210 contained within an internal space defined by pod 202 and door 208. The wafer container 200 can be any such suitable container for holding one or more wafers, for example, a standard mechanical interface (SMIF) pod. The wafer container 200 can be used to hold one or more wafers, for example, during processing, transport, and/or storage of semiconductor wafers.

Pod 202 in part defines the internal space of wafer container 200. Pod 202 can include a one or more side walls 204 and a closed end 206, with an open end (not shown) opposite the closed end. The one or more side walls 204 can be any number and arrangement of side walls forming a continuous wall such that the one or more side walls 204 can define an internal space along with the closed end 206 when the open end is sealed such as by door 208. In an embodiment, there is one side wall 204 that is a continuous, curved wall. In an embodiment, the one or more side walls are four side walls 204, forming a rectangular or square shape. The pod 202 can include one or more mounting features (not shown) on a side of the closed end 206 that is facing the internal space. The one or more mounting features can be positioned to correspond to the one or more mounting bosses of cassette hold down 214. The open end can accommodate door 208. When door 208 is attached, the pod 202 and door 208 can define an internal space configured to accommodate the wafer cassette 210 and cassette hold down 214.

Door 208 is a part of wafer container 200 configured to close the open end of pod 202. Door 208 can have a shape generally similar to that defined by the one or more side walls 204 of pod 202. Door 208 can include one or more engagement features to join door 208 to pod 202 to enclose the wafer container 200. Door 208 can be configured such that wafer cassette 210 can rest on door 208 on a side of door 208 that faces the internal space of wafer container 200 when wafer container 200 is assembled. Door 208 can be sized such that it is the same size or larger than a footprint of the wafer cassette 210. The door 208 can have a plane defined by its length and width directions.

A channel 228 can be formed on a side of door 208 facing the internal space of wafer container 200 when the wafer container 200 is assembled. The channel 228 can be a groove or depression, or a channel defined by side walls extending vertically from the door 208. The channel 228 can extend in, for example, the width direction of the door 208. In an embodiment, the channel 228 can be located at or near the midline of the door 208 in a length direction of the door 208. The channel 228 can be sized to accommodate the horizontal bar of wafer cassette 210. The channel 228 can extend some or all of the width of the door 208.

Wafer cassette 210 is a container configured to accommodate one or more wafers such as semiconductor wafers in an internal space. Each of the one or more wafers can be held in one or more wafer supports extending into the internal space from walls of the wafer cassette 210. The wafer cassette 210 can include a handle 212 on a wall of the wafer cassette 210. In an embodiment, the handle 212 extends in a vertical direction from a top wall of the wafer cassette 210.

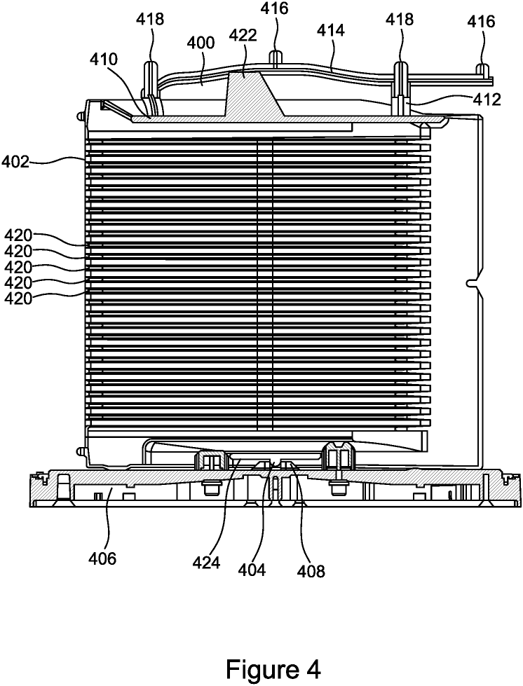

A horizontal bar (not shown) can be provided on a wall of wafer cassette 210 that faces door 208 when wafer container 200 is assembled. The horizontal bar extends in a width direction of the wafer cassette. The horizontal bar can project vertically outwards from the wall of wafer cassette 210 that it is provided on, away from the internal space defined by the wafer cassette. The horizontal bar can be located at or near the midline of the wafer cassette 210 in the length direction. In an embodiment, the horizontal bar can be in a recess formed in the wall of wafer cassette 210 that it is provided on, such that it does not project further than surfaces of wafer cassette 210 configured to contact door 208. The horizontal bar is shown in FIG. 4 and described in further detail below.

The cassette hold down 214 can be the cassette hold down 100 shown in FIG. 1 and described above. In the wafer container 200, the first cassette contact 216 and the second cassette contact 218 contact the wafer cassette 210 on either side of the horizontal bar in the plane of the door 208. In an embodiment, the first cassette contact 216 and the second cassette contact 218 can be on opposing sides of the handle 212 of wafer cassette 210. In an embodiment, the mounting bosses 220 mechanically interface with one or more mounting features (not shown) formed in pod 202. The cassette hold down 214 can be held in place relative to pod 202 by the interface of the mounting bosses 220 with the mounting features. When the wafer container 200 is assembled, the stoppers 222 can be spaced apart from an inside of the pod 202 by a gap under ordinary conditions, with the stoppers 222 being capable of contacting the inside of the pod when frame 224 and/or spring 226 flex, such as when the wafer container 200 is exposed to a mechanical shock. When the stoppers 222 contact pod 202, they can prevent further movement of first cassette contact 216 and/or second cassette contact 218, restricting further movement of the wafer cassette 210.

When wafer container 200 is assembled, the first and second cassette contacts 216 and 218 can be on opposing sides of the horizontal bar and the channel with respect to the plane of the door 208. Contact between the first and second cassette contacts 216 and 218 can provide force resisting rocking of the horizontal bar within the channel. The cassette hold down 214 when installed into wafer container 200 can reduce the chances of the wafer cassette being dislodged from its proper position within the wafer container 200. In an embodiment, the cassette contacts 216 and 218 each have a domed shape. The domed shape can reduce a point of contact between each of the cassette contacts 216 and 218. The domed shape can further provide rolling contact as opposed to a sharp point contacting the cassette.

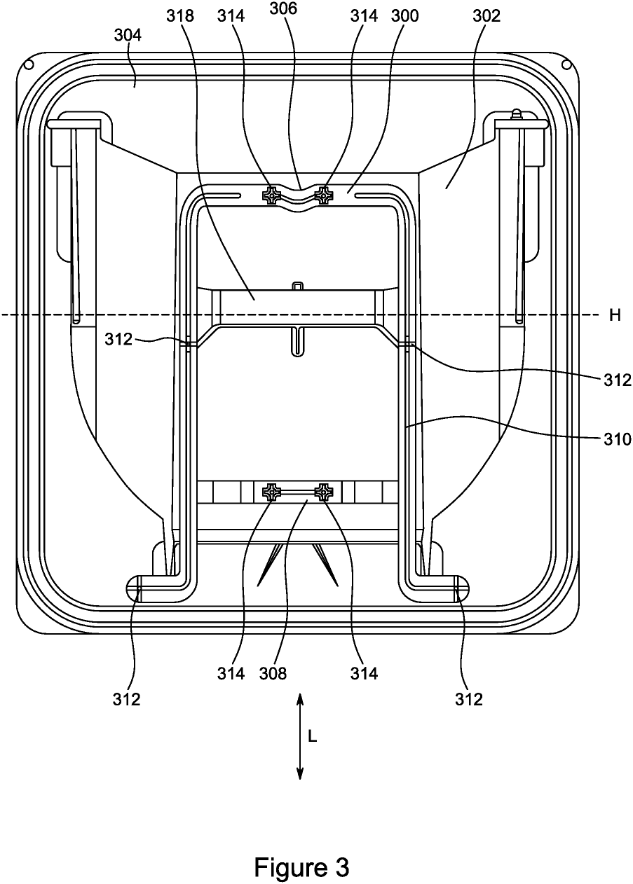

FIG. 3 shows a top view of a wafer cassette, a wafer container door, and a cassette hold down according to an embodiment. The cassette hold down 300 is provided over the wafer cassette 302. The wafer cassette in turn is resting on wafer container door 304.

Cassette hold down 300 is a cassette hold down according to an embodiment, such as cassette hold down 100 or cassette hold down 214 shown in FIGS. 1 and 2 respectively and described above. In the top view of FIG. 3, the first cassette contact 306 and the second cassette contact 308 can be seen, spaced apart in the length direction L of frame 310. Frame 310 can be shaped such that it surrounds handle 318 of the wafer cassette 302. Mounting bosses 312 are provided on the top side of frame 310. Mounting bosses 312 extend upwards from the frame 310 such that they can engage with a pod in a wafer container. Stoppers 314 are located at each of the first cassette contact 306 and the second cassette contact 308. The second cassette contact 308 is joined to frame 310 by the springs 316.

Wafer cassette 302 is a wafer cassette such as wafer cassette 210 described above and shown in FIG. 2. Wafer cassette 302 includes handle 318 provided on the top surface of the wafer cassette 302. Wafer cassette 302 includes a horizontal bar, such as the horizontal bar described herein and shown in FIG. 4, which is not visible in the top view of FIG. 3. Horizontal line H corresponds to the center line of the horizontal bar of wafer cassette 302. As can be seen, the spacing and positioning of first cassette contact 306 and second cassette contact 308 in the length direction L is such that first cassette contact 306 and second cassette contact 308 are on opposite sides of the horizontal line H.

Wafer container door 304 is below wafer cassette 302. Wafer container door 304 can be any suitable door for closing a wafer container, such as door 208 for wafer container 200 shown in FIG. 2 and described above. Wafer container door has a larger size than the footprint of wafer cassette 302, as can be seen here where wafer container door 304 remains visible from a top view while wafer cassette 302 is resting on it. The wafer container door is sized to close an open end of a pod such as pod 202 described above and shown in FIG. 2.

The combination of the cassette hold down 300, wafer cassette 302, and wafer container door 304 can be assembled with a pod such as pod 202 described above and shown in FIG. 2 to form a complete wafer container. Mounting bosses 312 of cassette hold down 300 can interface mechanically with mounting features of such a pod, and stoppers 314 can contact the pod when shocks are applied to the resulting wafer container.

FIG. 4 shows a sectional view of a door of a wafer container, a wafer cassette, and a cassette hold down according to an embodiment. The sectional view of FIG. 4 includes cassette hold down 400, wafer cassette 402 including horizontal bar 404, and door 406 including channel 408.

Cassette hold down 400 includes first cassette contact 410, second cassette contact 412, frame 414, mounting bosses 416, and stoppers 418. Cassette hold down 400 can be, for example, any of the cassette hold downs 100, 214, or 300 shown in FIGS. 1-3 and described above. First cassette contact 410 and second cassette contact 412 contact the wafer cassette 402, restricting movement of the wafer cassette within a wafer container. The frame 414 joins the elements of cassette hold down 400. Mounting bosses 416 are provided such that the cassette hold down can engage a pod of a wafer container, for example to secure and position the cassette hold down. Stoppers 418 can limit vertical motion of the first and second cassette contacts 410 and 412, for example to set stops at maximum amounts of deflection of one or both of first and second cassette contacts 410 and 412.

Wafer cassette 402 defines an internal space for storing one or more wafers. Wafer cassette 402 includes wafer supports 420, each extending into the internal space such that it is configured to at least partially support a wafer within the wafer cassette 402. Handle 422 extends above the body of wafer cassette 402, on a side opposite the side facing door 406.

Wafer cassette 402 includes horizontal bar 404 formed on the side facing door 406. Horizontal bar 404 extends in a vertical direction from a surface of the wafer cassette 402 towards the door 406. In an embodiment, horizontal bar 404 is provided in a depression 424 in the side of wafer cassette 402 facing door 406, such that it does not project further than other surfaces of wafer cassette 402 also contacting door 406. In an embodiment, horizontal bar 404 is received in channel 408 formed in door 406. In FIG. 4, the center line of horizontal bar 404 is illustrated with vertical line H for reference. As can be seen, first cassette contact 410 and second cassette contact 412 are spaced apart and positioned such that they are on opposing sides of the center line of horizontal bar 404. In an embodiment, first cassette contact 410 and second cassette contact 412 can be completely offset from the such that they are each over no part of the horizontal bar 404, and are on opposing sides of the entire horizontal bar 404.

Door 406 supports wafer cassette 402. Door 406 can be any suitable door for closing a wafer container, such as door 208 for wafer container 200 shown in FIG. 2 and described above or door 304 shown in FIG. 3 and described above. Channel 408 is formed in door 406. Channel 408 can be a groove, channel, or depression provided on door 406 and capable of accommodating at least a portion of the horizontal bar 404. Channel 408 can be defined by, for example, raised sides extending upwards from a side of door 406 that faces the internal space when door 406 is assembled into a wafer container. Channel 408 can, for example, assist in the positioning and securement of wafer cassette 402 through the horizontal bar being received in the channel 408. In an embodiment, first cassette contact 410 and second cassette contact 412 are located on opposing sides of channel 408 in the plane of door 406.

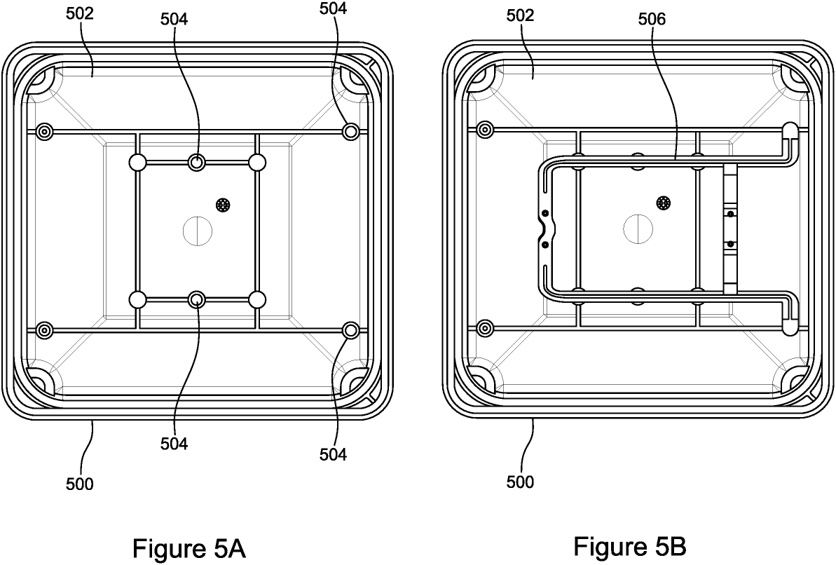

FIG. 5A shows a bottom view of a pod of a wafer container according to an embodiment. In the bottom view of pod 500, the side of the closed end facing an inside of the pod 502 can be seen. Mounting features 504 are provided at predefined points on the side of the closed end facing the inside of the pod 502. The mounting features 504 can be any suitable mechanical interface for engaging mounting bosses such as mounting bosses 110, 220, 312, or 416 described above and shown in FIGS. 1-4. In an embodiment, the mounting features 504 are holes, such as drilled holes, sized to accommodate the mounting bosses while providing a press-fit when the mounting bosses are inserted. FIG. 5B shows a bottom view of the pod 500 of a wafer container shown in FIG. 5A and a cassette hold down according to an embodiment. The cassette hold down 506 is shaped to correspond to the positions of the mounting features 504 visible in FIG. 5A, such that mounting bosses (not shown) on the cassette hold down 506 align with the mounting features, and the mounting bosses and mounting features mechanically interface to align and retain cassette hold down 506 to pod 500. The mounting bosses can be, for example, mounting bosses 110, 220, 312, or 416 described above and shown in FIGS. 1-4.

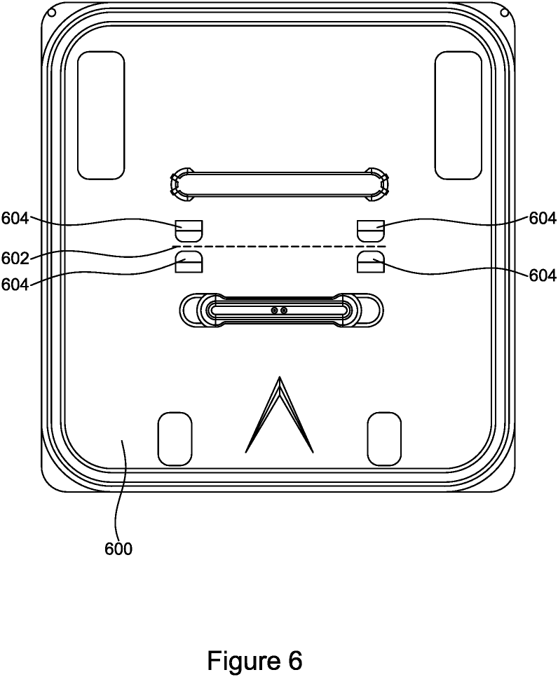

FIG. 6 shows a top view of a door of a wafer container according to an embodiment. Door 600 includes a channel 602, shown as the dashed line, defined by two opposing pairs of projections 604. The channel 602 can be sized to accommodate a horizontal bar included in a wafer cassette, such as any horizontal bars described above and horizontal bar 404 shown in FIG. 4. FIG. 6 shows two opposing pairs of the projections 604 defining the channel 602 by providing a space between each pair allowing a horizontal bar to be retained therein. However, the channel 602 can be defined by any suitable physical structure, such as additional pairs of projections, one pair of continuous projections, or the like.

### Aspects

It is understood that any of aspects 1-4 can be combined with any of aspects 5-10.

Aspect 1. A cassette hold down, comprising:
a frame;
a first cassette contact extending from the frame in a vertical direction on a first side of the frame; and
a second cassette contact extending from the frame in the vertical direction on the first side the of the frame;
wherein the first cassette contact is spaced apart from the second cassette contact in a length direction of the frame.

Aspect 2. The cassette hold down according to aspect 1, further comprising a plurality of mounting bosses, each of the mounting bosses extending in the vertical direction on a second side of the cassette hold down, opposite the first side.

Aspect 3. The cassette hold down according to any of aspects 1 or 2, wherein each of the first cassette contact and the second cassette contact each include one or more stoppers extending in the vertical direction on a second side of the cassette hold down, opposite the first side, and each of the one or more stoppers are positioned on one of the first cassette contact or the second cassette contact.

Aspect 4. The cassette hold down according to any of aspects 1-3, further comprising a spring connecting the second cassette contact to the frame, the spring configured to allow vertical movement of the second cassette contact relative to the frame.

Aspect 5. A wafer container, comprising:
a pod including one or more side walls, a closed end, an internal space defined by the one or more side walls and the closed end, and an open end
a door, the door configured to close the open end of the pod, the door including a channel;
a wafer cassette including a bar configured to be received in the channel of the door; and
a cassette hold down, including:
a frame;
a first cassette contact extending from the frame in a vertical direction on a first side of the frame; and
a second cassette contact extending from the frame in the vertical direction on the first side the of the frame;
wherein when the wafer cassette and the cassette hold down are located in the internal space and the door is closing the open end, the first cassette contact and the second cassette contact are in contact with the wafer cassette on opposing sides of the bar, in the plane of the door.

Aspect 6. The wafer container according to aspect 5, wherein a side of the closed end facing the internal space includes a plurality of mounting features, and the cassette hold down includes a plurality of mounting bosses each configured to engage with at least one of said mounting features.

Aspect 7. The wafer container according to aspect 6, wherein each of the plurality of mounting features is a hole formed in the side of the closed end facing the internal space.

Aspect 8. The wafer container according to any of aspects 5-7, wherein the cassette hold down includes a plurality of stoppers configured to extend towards a side of the closed end facing the internal space when the wafer cassette and the cassette hold down are located in the internal space and the door is closing the open end, and each of the plurality of stoppers are positioned on one of the first cassette contact or the second cassette contact.

Aspect 9. The wafer container according to any of aspects 5-8, further comprising a spring connecting the second cassette contact to the frame, the spring configured to allow vertical movement of the second cassette contact relative to the frame.

Aspect 10. The wafer container according to any of aspects 5-9, wherein the wafer container is a standard mechanical interface (SMIF) pod.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A cassette hold down, comprising:
a frame;
a first cassette contact extending from the frame in a vertical direction on a first side of the frame; and
a second cassette contact extending from the frame in the vertical direction on the first side the of the frame;
wherein the first cassette contact is spaced apart from the second cassette contact in a length direction of the frame.

2. The cassette hold down of claim 1, further comprising a plurality of mounting bosses, each of the mounting bosses extending in the vertical direction on a second side of the cassette hold down, opposite the first side.

3. The cassette hold down of claim 1, wherein each of the first cassette contact and the second cassette contact each include one or more stoppers extending in the vertical direction on a second side of the cassette hold down, opposite the first side, and each of the one or more stoppers are positioned on one of the first cassette contact or the second cassette contact.

4. The cassette hold down of claim 1, further comprising a spring connecting the second cassette contact to the frame, the spring configured to allow vertical movement of the second cassette contact relative to the frame.

5. A wafer container, comprising:
a pod including one or more side walls, a closed end, an internal space defined by the one or more side walls and the closed end, and an open end
a door, the door configured to close the open end of the pod, the door including a channel;
a wafer cassette including a bar configured to be received in the channel of the door; and
a cassette hold down, including:
a frame;
a first cassette contact extending from the frame in a vertical direction on a first side of the frame; and
a second cassette contact extending from the frame in the vertical direction on the first side the of the frame;
wherein when the wafer cassette and the cassette hold down are located in the internal space and the door is closing the open end, the first cassette contact and the second cassette contact are in contact with the wafer cassette on opposing sides of the bar, in the plane of the door.

6. The wafer container of claim 5, wherein a side of the closed end facing the internal space includes a plurality of mounting features, and the cassette hold down includes a plurality of mounting bosses each configured to engage with at least one of said mounting features.

7. The wafer container of claim 6, wherein each of the plurality of mounting features is a hole formed in the side of the closed end facing the internal space.

8. The wafer container of claim 5, wherein the cassette hold down includes a plurality of stoppers configured to extend towards a side of the closed end facing the internal space when the wafer cassette and the cassette hold down are located in the internal space and the door is closing the open end, and each of the plurality of stoppers are positioned on one of the first cassette contact or the second cassette contact.

9. The wafer container of claim 5, further comprising a spring connecting the second cassette contact to the frame, the spring configured to allow vertical movement of the second cassette contact relative to the frame.

10. The wafer container of claim 5, wherein the wafer container is a standard mechanical interface (SMIF) pod.
